(19) United States
(12) Patent Application Publication
(10) Pub. No.: US 2006/0091567 A1
(43) Pub. Date: May 4, 2006

(54) Cavity-down Package and Method for Fabricating the same

(76) Inventors: Yu-Liang Lin, Kao-Hsiung City (TW); Chih-Cheng Hung, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/163,131

(22) Filed: Oct. 6, 2005

(30) Foreign Application Priority Data
Oct. 28, 2004 (TW) 093132774

(51) Int. Cl. H01L 23/28

(52) U.S. Cl. 257/787

(57) ABSTRACT

A method for fabricating a cavity-down package is provided. A chip carrier includes a chip cavity. A chip is disposed inside the cavity, and a plurality of bonding materials is formed at the corners of the chip. The bonding materials are cured to protect the corners of the chip. Next, an encapsulant is formed in the cavity to seal the chip and the bonding materials to prevent stress concentration caused by thermal expansion mismatch on the chip corners and eliminate delamination between the encapsulant and the chip.

### BACKGROUND OF THE INVENTION

1. Field of the Invention

The invention relates to a cavity-down package and method for fabricating the same, and more particularly, to a cavity-down package fabrication method of protecting the corner or edge of a chip before the encapsulating process.

2. Description of the Prior Art

Cavity-down packages are common packaging forms used in the semiconductor industry. Cavity-down packages have advantages over other forms, such as: better heat dissipation and shorter distance for electrical conductivity.

Please refer to FIG. 1. FIG. 1 is a perspective diagram showing the cross-section of a cavity-down package 100 according to the prior art. As shown in FIG. 1, a chip carrier 110 is composed of a heat dissipater 111 and a circuit board 112 having an opening and a bonding surface 113, in which the opening of the circuit board 112 and the heat dissipater 111 together form a cavity 114 of the chip carrier 110. Additionally, a chip 120 is disposed in the cavity 114, a plurality of wires 130 are electrically connected to the circuit board 112, an encapsulant 140 is filled within the cavity 114 to seal the chip 120 and the wires 130, and a plurality of solder balls 150 are formed on the bonding surface 113 of the circuit board 112. Due to different degrees of expansion and compression between the encapsulant 140 and the chip 120 caused by and occurring during the curing process, stress will accumulate at the corners 121 or other edges of the chip 120 and result in delamination problems.

Please refer to FIG. 2a through FIG. 2e. FIG. 2a through FIG. 2e are top-view diagrams showing the process of fabricating a cavity-down package 100 according to the prior art. As shown in FIG. 2a, the cavity 114 of the chip carrier 110 is located toward the bonding surface 113 of the circuit board 112 and during the bonding process, the chip 120 is disposed in the cavity 114 and bonded to the heat dissipater 111. Next, as shown in FIG. 2b, a wire bonding process is performed to electrically connect the circuit board 112 and the chip 120 with the plurality of wires 130. As shown in FIG. 2c, the encapsulant 140 is filled within the cavity 114 to seal the chip 120 and the wires 130. As shown in FIG. 2d, a curing process is performed to cure the encapsulant 140. As shown in FIG. 2e, the plurality of solder balls 150 is formed on the bonding surface 113 to form the conventional cavity-down package 110. However, during the process of fabricating the cavity-down package 100, a coating process is usually performed to form the encapsulant 140 and as a result of the expansion and shrinkage caused by and occurring during the curing process of the encapsulant 140 and the different expansion coefficient between the encapsulant 140 and the chip 120, stress will accumulate at the corners 121 or edges of the chip 120 and result in the phenomenon such as delamination. Consequently, production yield will greatly decrease and cost of production will increase. Moreover, when more structurally fragile low k chips are utilized for fabricating the chip, this condition will become increasingly worse.

### SUMMARY OF THE INVENTION

It is therefore an objective of the claimed invention to provide a method for fabricating a cavity-down package, in which the method includes first disposing a chip in the cavity of a chip carrier. Next, a plurality of bonding materials is formed at the corners or edges of the chip and a curing process is performed to cure the bonding materials for protecting the corners or edges of the chip. Next, an encapsulant is formed in the cavity and another curing process is performed to cure the encapsulant. Preferably, the bonding materials can be utilized to protect the corners or edges of the cavity and prevent delamination between the chip and the encapsulant, which results from the expansion and shrinkage phenomenon while the encapsulant is being cured.

It is another aspect of the claimed invention to provide a cavity-down package. The cavity-down package includes a chip carrier having a surface and a cavity; a chip disposed in the cavity of the chip carrier, in which the chip includes a plurality of corners; a plurality of bonding materials formed in the corners of the chip, in which the bonding materials are cured to protect the corners of the chip; and an encapsulant formed in the cavity for sealing the chip and the bonding materials. Preferably, the bonding materials are formed to protect the corners of the chip, such that when the encapsulant is formed to cover the chip and the bonding materials, no delamination will result between the corners of the chip and the encapsulant.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective diagram showing the cross-section of a cavity-down package according to the prior art.

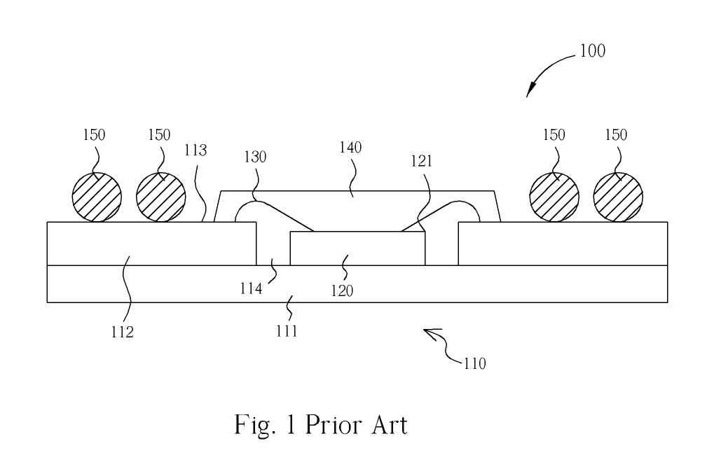

FIG. 2a through FIG. 2e are top-view diagrams showing the process of fabricating a cavity-down package according to the prior art.

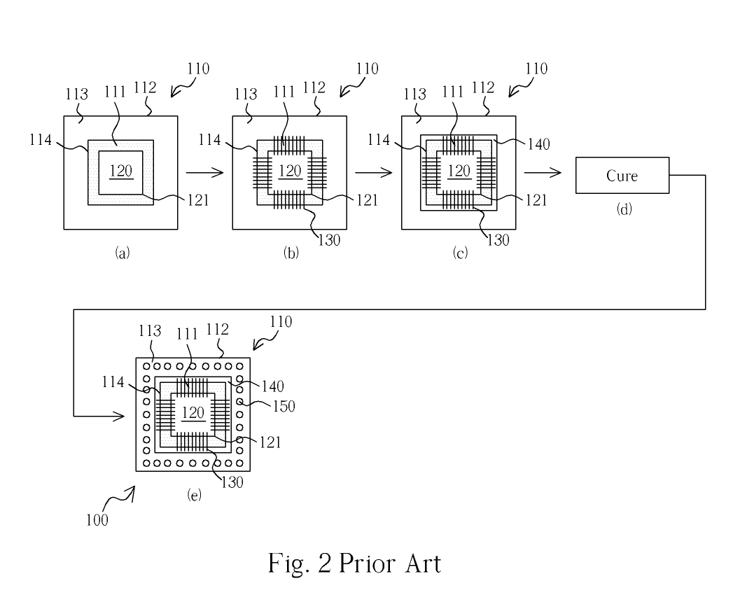

FIG. 3 is a perspective diagram showing the cross-section of a cavity-down package according to a first embodiment of the present invention.

FIG. 4a through FIG. 4g are top-view diagrams showing the process of fabricating a cavity-down package according to the first embodiment of the present invention.

FIG. 5a through FIG. 5g are top-view diagrams showing the process of fabricating a cavity-down package according to a second embodiment of the present invention.

### DETAILED DESCRIPTION

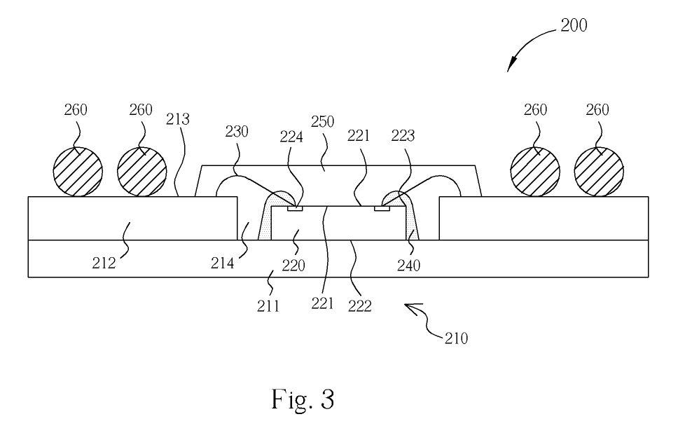

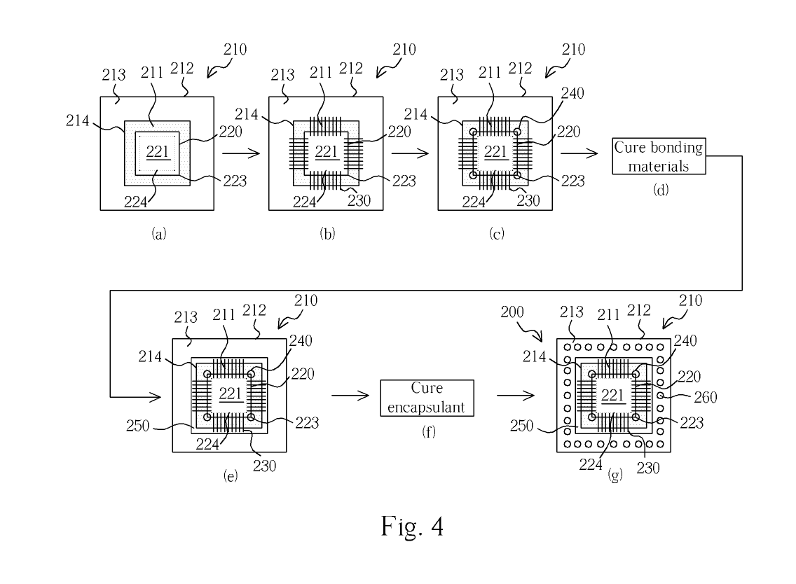

Please refer to FIG. 3 and FIG. 4. FIG. 3 is a perspective diagram showing the cross-section of a cavity-down package according to the first embodiment of the present invention and FIG. 4a through FIG. 4g are top-view diagrams showing the process of fabricating a cavity-down package according to the first embodiment of the present invention. As shown in FIG. 4a, a chip carrier 210 composed of a heat dissipater 211 and a circuit board 212 is provided, in which the chip carrier 210 includes a surface 213 and a cavity 214 facing the surface 213. Preferably, the surface 213 is an exposed surface of the circuit board 212 for serving as a bonding surface to the outside; and the cavity 214 of the chip carrier 210 is formed by the opening of the circuit board 212 and the heat dissipater 211. Additionally, the heat dissipater 211 is composed of copper or other metals and the circuit board 212 is composed of reinforced fiber including FR-3, FR-4 epoxy or BT resin substrate, polyimide, or ceramic substrate. Next, a bonding process is performed to dispose a chip 220 into the cavity 214. According to the present embodiment, the chip 220 is a low k chip, in which the chip 220 includes an active surface 221, a back surface 222, a plurality of corners 223, and a plurality of solder pads 224 formed on the active surface 221. Preferably, the back surface 222 is attached to the heat dissipater 211, and the corners 223 are located remotely corresponding to the back surface 222.

As shown in FIG. 4b, a wire bonding process is performed to form a plurality of wires 230 to electrically connect the solder pads 224 to the circuit board 212. As shown in FIG. 4c, a plurality of bonding materials 240 is formed at the corners 223 of the chip 220. Preferably, the bonding materials 240 are disposed on the heat dissipater 211 to cover the corners 223 of the chip 220, in which the bonding materials 240 are formed by a liquid coating process and composed of materials having heat curing or light curing properties, such that the bonding materials 240 can be cured by a heating or light irradiation process. As shown in FIG. 4d, a curing process is performed by utilizing a baking process or light irradiation to cure the bonding materials 240 to protect the corners 223 of the chip 220. As shown in FIG. 4e, an encapsulant 250 is formed in the cavity 214 by liquid coating or transfer molding to cover the chip 220, the wires 230, and the bonding materials 240, in which the encapsulant 250 and the bonding materials 240 may be composed of same materials. As shown in FIG. 4f, another curing process is performed to cure the encapsulant 250, in which the baking equipment and baking condition utilized to cure the encapsulant 250 can be identical to the baking equipment and baking condition utilized for the bonding materials 240.

Hence, the method for fabricating the cavity-down package 200 essentially uses the two steps of forming the bonding materials 240 and the encapsulant 250 to prevent delamination between the corners 223 of the chip 220 and the encapsulant 250. Subsequently, as shown in FIG. 4g, a plurality of solder balls 260 is disposed over the surface 213 of the chip carrier 210 to form the cavity-down package 200.

As shown in FIG. 3, the cavity-down package 200 is produced by utilizing the method described above, in which the cavity-down package 200 includes a chip carrier 210 composed of a heat dissipater 211 and a circuit board 212. Preferably, the chip carrier 210 includes a surface 213 and a cavity 214 facing toward the surface 213, in which the surface 213 is an exposed surface of the circuit board 212 for serving as a bonding surface to the outside. The surface 213 also includes a plurality of solder ball pads (not shown) for connecting to the plurality of solder balls 260. Additionally, a chip 220 is disposed in the cavity 214, in which the chip 220 includes an active surface 221, a back surface 221, a plurality of corners 223, and a plurality of solder pads 224 formed on the active surface 221. Preferably, the solder pads 224 are electrically connected to the circuit board 212 by using a plurality of wires 230, and a plurality of bonding materials 240 are formed at the corners 223 and covering the heat dissipater 211 to protect the corners 223. Moreover, an encapsulant 250 is formed in the cavity 214 to cover the chip 220, the bonding materials 240, and the wires 230.

According to the method of fabricating the cavity-down package of the present invention, the bonding materials 240 are formed at the corners 223 of the active surface 221 before the encapsulant 250 are formed, such that the bonding materials 240 can be utilized to protect the corners 223 of the cavity 214 and prevent delamination between the corners 233 and the encapsulant 250 while the encapsulant 250 is being cured.

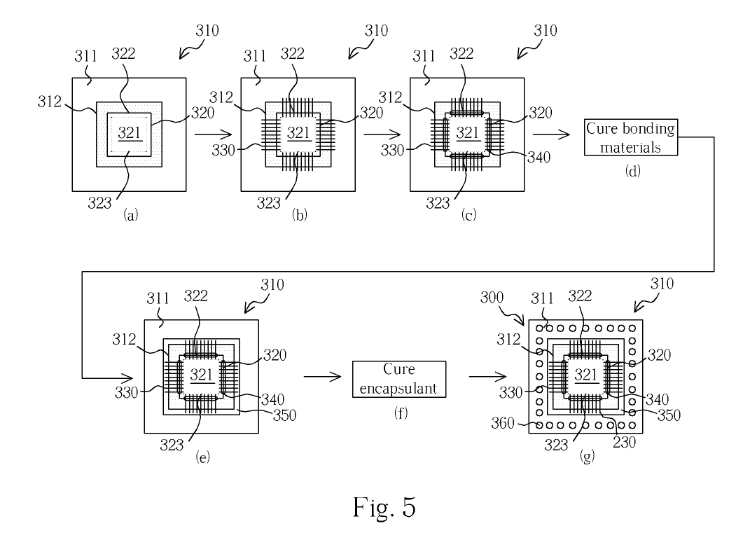

Additionally, the location of the bonding materials can be adjusted accordingly depending on the location of the delamination. Please refer to FIG. 5a through FIG. 5g. FIG. 5a through FIG. 5g are top-view diagrams showing the process of fabricating a cavity-down package according to the second embodiment of the present invention. As shown in FIG. 5a, a chip carrier 310 includes an exposed surface 311 and a cavity 312 facing toward the surface 311, in which the chip carrier 310 is a circuit board. Next, a bonding process is performed to dispose a chip 320 in the cavity 312, in which the chip 320 includes an active surface 321 and a plurality of solder pads 323 formed on the active surface 321. Preferably, the active surface includes a plurality of edges 322 and the chip 320 is attached to the bottom of the cavity 312.

As shown in FIG. 5b, a wire bonding is performed to form a plurality of wires 330 to electrically connect the solder pads 323 of the chip 320 to the chip carrier 310. As shown in FIG. 5c, a plurality of bonding materials 340 are formed at the edges 322 of the chip 320, in which the edges 322 are the part of the chip 320 more prone to delamination. Preferably, the bonding materials 340 are extended to the bottom (not shown) of the cavity 312. As shown in FIG. 5d, a curing process is performed to cure the bonding materials 340 and protect the edges 322 of the chip 320. As shown in FIG. 5e, an encapsulant 350 is formed in the cavity 312 to cover the chip 320, the wires 330, and the bonding materials 340. As shown in FIG. 5f, the encapsulant 350 is cured by the curing process and as shown in FIG. 5g, a plurality of solder balls 360 is formed over the surface 311 of the chip carrier 310 to form a cavity-down package 300.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a cavity-down package comprising:
providing a chip carrier, wherein the chip carrier comprises a surface and a cavity;
disposing a chip in the cavity, wherein the chip comprises a plurality of corners;
forming a plurality of bonding materials at the corners of the chip;
curing the bonding materials for protecting the corners of the chip; and
forming an encapsulant in the cavity for sealing the chip and the bonding materials.

2. The method of claim 1, wherein the bonding materials comprise heat curing properties and the process of curing the bonding materials comprises heat baking.

3. The method of claim 1, wherein the bonding materials comprise light curing properties.

4. The method of claim 1, wherein the bonding materials are completely cured before the formation of the encapsulant.

5. The method of claim 1, wherein the formation of the bonding materials comprises liquid coating.

6. The method of claim 1, wherein the chip comprises a low k chip.

7. A method for fabricating a cavity-down package comprising:
providing a chip carrier, wherein the chip carrier comprises a surface and a cavity;
disposing a chip in the cavity, wherein the chip comprises a plurality of edges;
forming a plurality of bonding materials at the edges of the chip;
curing the bonding materials for protecting the edges of the chip; and
forming an encapsulant in the cavity for sealing the chip and the bonding materials.

8. The method of claim 7, wherein the bonding materials comprise heat curing properties and the process of curing the bonding materials comprises heat baking.

9. The method of claim 7, wherein the bonding materials comprise light curing properties.

10. The method of claim 7, wherein the formation of the bonding materials comprises liquid coating.

11. The method of claim 7, wherein the chip comprises a low k chip.

12. A cavity-down package comprising:
a chip carrier having a surface and a cavity;
a chip disposed in the cavity of the chip carrier;
a plurality of bonding materials formed on the coners or the sides of the chip, wherein the bonding materials are cured to protect the chip; and
an encapsulant formed in the cavity for sealing the chip and the bonding materials.

13. The cavity-down package of claim 12, wherein the bonding materials comprise heat curing properties.

14. The cavity-down package of claim 12, wherein the bonding materials comprise light curing properties.

15. The cavity-down package of claim 12, wherein the chip comprises a low k chip.
